(19) United States
(12) Patent Application Publication
(10) Pub. No.: US 2018/0048305 A1
(43) Pub. Date: Feb. 15, 2018

(54) RADIO-FREQUENCY SWITCH WITH SWITCHABLE CAPACITOR

(71) Applicant: SKYWORKS SOLUTIONS, INC., Woburn, MA (US)

(72) Inventors: Yalin JIN, San Jose, CA (US); Reza KASNAVI, Solana Beach, CA (US); Ying SHI, Saratoga, CA (US)

(21) Appl. No.: 15/653,457

(22) Filed: Jul. 18, 2017

Related U.S. Application Data
(60) Provisional application No. 62/372,728, filed on Aug. 9, 2016.
(60) Provisional application No. 62/372,734, filed on Aug. 9, 2016.

(51) Int. Cl. H03K 17/16; H01L 23/66; H01L 27/092

(52) U.S. Cl. CPC H03K 17/162; H01L 27/0928; H01L 23/66; H01L 29/1095

(57) ABSTRACT

Radio-frequency switch with switchable capacitor. In some embodiments, a RF switch includes a first field-effect transistor (FET) disposed between an input node and an output node. The RF switch also includes a switchable capacitor disposed between the input node and the output node, the switchable capacitor coupled in parallel with the first FET.

### CROSS-REFERENCE TO RELATED APPLICATION(S)

This application claims priority to U.S. Provisional Application No. 62/372,728 filed Aug. 9, 2016, entitled RADIO-FREQUENCY SWITCH WITHOUT NEGATIVE VOLTAGES and U.S. Provisional Application No. 62/372,734 filed Aug. 9, 2016, entitled RADIO-FREQUENCY SWITCH WITH SWITCHABLE CAPACITOR, the disclosures of which are hereby expressly incorporated by reference herein in their respective entireties.

### BACKGROUND

### Field

The present disclosure generally relates to the field of electronics, and more particularly, to radio-frequency switches.

### Description of the Related Art

Radio-frequency (RF) switches, such as transistor switches, can be used to switch signals between one or more poles and one or more throws. Transistor switches, or portions thereof, can be controlled through transistor biasing and/or coupling. Design and use of bias and/or coupling circuits in connection with RF switches can affect switching performance.

### SUMMARY

In some implementations, the present disclosure relates to a radio-frequency (RF) switch. The RF switch includes a first field-effect transistor (FET) disposed between an input node and an output node. The RF switch also includes a switchable capacitor disposed between the input node and the output node, the switchable capacitor coupled in parallel with the first FET.

In some embodiments, the first FET comprises a gate, a body, a drain and a source.

In some embodiments, the input node is coupled to the source and the output node is coupled to the drain.

In some embodiments, the switchable capacitor is coupled to the drain and the source.

In some embodiments, the switchable capacitor is ON when the first FET is ON.

In some embodiments, the switchable capacitor is OFF when the first FET is OFF.

In some embodiments, the RF switch further includes a resistor coupled to the gate.

In some embodiments, the output node is configured to output a RF signal when the first FET is in an ON state.

In some embodiments, the RF switch further includes additional FETs connected in series to the first FET, a number of additional FETs selected to allow the RF switch to handle a power of a RF signal.

In some embodiments, the first FET is a silicon-on-insulator (SOI) FET.

In some implementations, the present disclosure relates to a method for operating a radio-frequency (RF) switch. The method includes controlling a first field-effect transistor (FET) disposed between first and second nodes so that the first FET is in a first ON state or a first OFF state. The method also includes controlling a switchable capacitor disposed between the first and second nodes so that the switchable capacitor is in a second ON state or a second OFF state.

In some embodiments, the method further includes placing the switchable capacitor in the first ON state when the first FET is in second ON state.

In some embodiments, the method further includes placing the switchable capacitor in the first OFF state when the first FET is in second OFF state.

In some implementations, the present disclosure relates to a semiconductor die. The semiconductor die includes a semiconductor substrate. The semiconductor die also includes a first field-effect transistor (FET) disposed between an input node and an output node. The semiconductor die further includes a switchable capacitor disposed between the input node and the output node, the switchable capacitor coupled in parallel with the first FET.

In some embodiments, the semiconductor die further includes an insulator layer disposed between the first FET and the semiconductor substrate.

In some embodiments, the semiconductor die is a silicon-on-insulator (SOI) die.

In some embodiments, the first FET comprises a gate, a body, a drain and a source.

In some embodiments, the input node is coupled to the source and the output node is coupled to the drain.

In some embodiments, the switchable capacitor is coupled to the drain and the source.

In some embodiments, the switchable capacitor is ON when the first FET is ON.

In some embodiments, the switchable capacitor is OFF when the first FET is OFF.

In some implementations, the present disclosure relates to a method for fabricating a semiconductor die. The method includes providing a semiconductor substrate. The method also includes forming a first field-effect transistor (FET) on the semiconductor substrate. The method further includes forming a switchable capacitor on the semiconductor substrate.

In some embodiments, the method further includes coupling the switchable capacitor to the first FET in parallel.

In some embodiments, the method further includes forming an insulator layer between the first FET and the semiconductor substrate.

In some implementations, the present disclosure relates to a radio-frequency (RF) switch module. The RF switch modules includes a packaging substrate configured to receive a plurality of components. The RF switch modules also includes a semiconductor die mounted on the packaging substrate, the semiconductor die including a first field-effect transistor (FET) disposed between an input node and an output node and a switchable capacitor disposed between the input node and the output node, the switchable capacitor coupled in parallel with the first FET.

In some embodiments, the semiconductor die is a silicon-on-insulator (SOI) die.

In some embodiments, the first FET comprises a gate, a body, a drain and a source.

In some embodiments, the input node is coupled to the source and the output node is coupled to the drain.

In some embodiments, the switchable capacitor is coupled to the drain and the source.

In some embodiments, the switchable capacitor is ON when the first FET is ON.

In some embodiments, the switchable capacitor is OFF when the first FET is OFF.

In some embodiments, the RF switch modules further includes a resistor coupled to the gate.

In some embodiments, the output node is configured to output a RF signal when the first FET is in an ON state.

In some embodiments, the RF switch modules further includes additional FETs connected in series to the first FET, a number of additional FETs selected to allow the RF switch to handle a power of a RF signal.

In some embodiments, the first FET is a silicon-on-insulator (SOI) FET.

In some implementations, the present disclosure relates to a wireless device. The wireless device includes a transceiver configured to process RF signals. The wireless device also includes an antenna in communication with the transceiver configured to facilitate transmission of an amplified RF signal. The wireless device further includes a power amplifier connected to the transceiver and configured to generate the amplified RF signal. The wireless device further includes a switch connected to the antenna and the power amplifier and configured to selectively route the amplified RF signal to the antenna, the switch including a first field-effect transistor (FET) disposed between an input node and an output node and a switchable capacitor disposed between the input node and the output node, the switchable capacitor coupled in parallel with the first FET.

In some embodiments, the first FET comprises a gate, a body, a drain and a source.

In some embodiments, the first FET comprises a gate, a body, a drain and a source.

In some embodiments, the input node is coupled to the source and the output node is coupled to the drain.

In some embodiments, the switchable capacitor is coupled to the drain and the source.

In some embodiments, the switchable capacitor is ON when the first FET is ON.

In some embodiments, the switchable capacitor is OFF when the first FET is OFF.

In some embodiments, the wireless device further includes a resistor coupled to the gate.

In some embodiments, output node is configured to output a RF signal when the first FET is in an ON state.

In some embodiments, the wireless device further includes additional FETs connected in series to the first FET, a number of additional FETs selected to allow a RF switch to handle a power of a RF signal.

In some embodiments, the first FET is a silicon-on-insulator (SOI) FET.

### BRIEF DESCRIPTION OF THE DRAWINGS

FIG. 1 schematically shows a radio-frequency (RF) switch configured to switch one or more signals between one or more poles and one or more throws.

FIG. 2 shows that the RF switch 100 of FIG. 1 can include an RF core and an energy management (EM) core.

FIG. 3 shows an example of the RF core implemented in an single-pole-double-throw (SPDT) configuration.

FIG. 4 shows an example of the RF core implemented in an SPDT configuration where each switch arm can include a plurality of field-effect transistors (FETs) connected in series.

FIG. 5 schematically shows that controlling of one or more FETs in an RF switch can be facilitated by a circuit configured to bias and/or couple one or more portions of the FETs.

FIG. 6 shows examples of the bias/coupling circuit implemented on different parts of a plurality of FETs in a switch arm.

FIGS. 7A and 7B show plan and side sectional views of an example finger-based FET device implemented in a silicon-on-insulator (SOI) configuration.

FIGS. 8A and 8B show plan and side sectional views of an example of a multiple-finger FET device implemented in an SOI configuration.

FIGS. 9A and 9B show an example RF switch, in accordance with some embodiments.

FIG. 10 shows example RF switches, in accordance with some embodiments.

FIGS. 11A and 11B show example first order models of RF switches, in accordance with some embodiments.

FIG. 12 is a flow diagram illustrating a method of operating a switch, in accordance with some embodiments.

FIG. 13 is a flow diagram illustrating a method of operating a switch, in accordance with some embodiments.

FIG. 14 is a flow diagram illustrating a method of fabricating a switch/module, in accordance with some embodiments.

FIG. 15 is a flow diagram illustrating a method of fabricating a switch/module, in accordance with some embodiments.

FIGS. 16A-16C illustrate harmonics related performance examples for switches, in accordance with some embodiments.

FIG. 17A-17F illustrate example voltages between different components, portions, and/or sections of a switches, in accordance with some embodiments.

FIGS. 18A-18D show examples of how various components for biasing, coupling, and/or facilitating the example configurations herein may be implemented, in accordance with some embodiments.

FIGS. 19A and 19B show an example of a packaged module that can include one or more features described herein.

FIG. 20 shows that in some embodiments, one or more features of the present disclosure can be implemented in a switch device such as a single-pole-multi-throw (SPMT) switch configured to facilitate multi-band multi-mode wireless operation.

FIG. 21 shows an example of a wireless device that can include one or more features described herein.

FIG. 22 shows that in some implementations, one or more features associated with a given example configuration can be combined with one or more features associated with another example configuration.

### DETAILED DESCRIPTION OF SOME EMBODIMENTS

The headings provided herein, if any, are for convenience only and do not necessarily affect the scope or meaning of the claimed invention.

Radio-frequency (RF) switches, such as transistor switches, can be used to switch signals between one or more poles and one or more throws. Transistor switches, or portions thereof, can be controlled through transistor biasing and/or coupling. Design and use of bias and/or coupling circuits in connection with RF switches can affect switching performance.

### Example Components of a Switching Device:

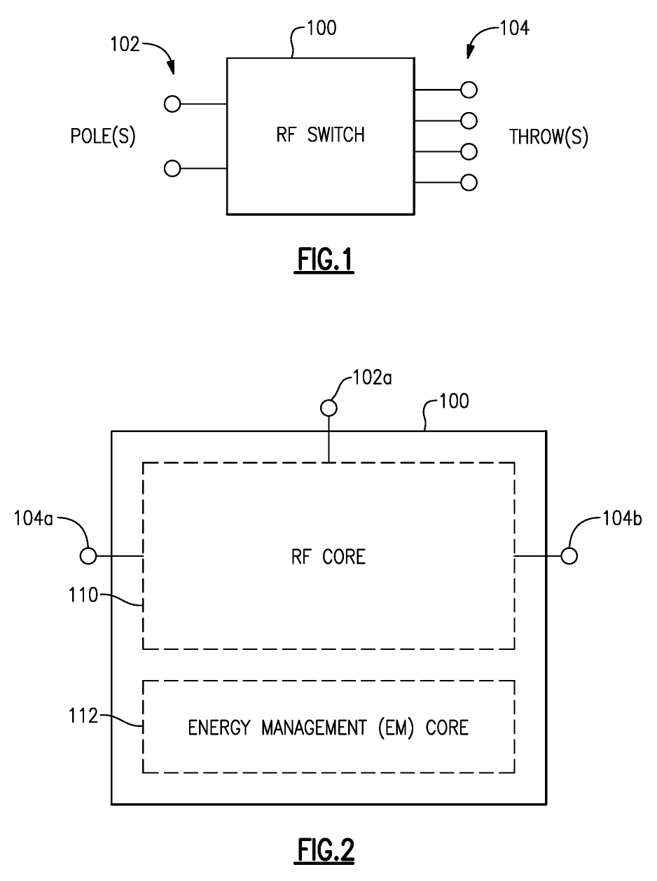

FIG. 1 schematically shows a radio-frequency (RF) switch 100 configured to switch one or more signals between one or more poles 102 and one or more throws 104. In some embodiments, such a switch can be based on one or more field-effect transistors (FETs) such as silicon-on-insulator (SOI) FETs. When a particular pole is connected to a particular throw, such a path is commonly referred to as being closed or in an ON state. When a given path between a pole and a throw is not connected, such a path is commonly referred to as being open or in an OFF state.

FIG. 2 shows that in some implementations, the RF switch 100 of FIG. 1 can include an RF core 110 and an energy management (EM) core 112. The RF core 110 can be configured to route RF signals between the first and second ports. In the example single-pole-double-throw (SPDT) configuration shown in FIG. 2, such first and second ports can include a pole 102a and a first throw 104a, or the pole 102a and a second throw 104b.

In some embodiments, EM core 112 can be configured to supply, for example, voltage control signals to the RF core. The EM core 112 can be further configured to provide the RF switch 100 with logic decoding and/or power supply conditioning capabilities.

In some embodiments, the RF core 110 can include one or more poles and one or more throws to enable passage of RF signals between one or more inputs and one or more outputs of the switch 100. For example, the RF core 110 can include a single-pole double-throw (SPDT or SP2T) configuration as shown in FIG. 2.

In the example SPDT context, FIG. 3 shows a more detailed example configuration of an RF core 110. The RF core 110 is shown to include a single pole 102a coupled to first and second throw nodes 104a, 104b via first and second transistors (e.g., FETs) 120a, 120b. The first throw node 104a is shown to be coupled to an RF ground via an FET 122a to provide shunting capability for the node 104a. Similarly, the second throw node 104b is shown to be coupled to the RF ground via an FET 122b to provide shunting capability for the node 104b.

In an example operation, when the RF core 110 is in a state where an RF signal is being passed between the pole 102a and the first throw 104a, the FET 120a between the pole 102a and the first throw node 104a can be in an ON state, and the FET 120b between the pole 102a and the second throw node 104b can be in an OFF state. For the shunt FETs 122a, 122b, the shunt FET 122a can be in an OFF state so that the RF signal is not shunted to ground as it travels from the pole 102a to the first throw node 104a. The shunt FET 122b associated with the second throw node 104b can be in an ON state so that any RF signals or noise arriving at the RF core 110 through the second throw node 104b is shunted to the ground so as to reduce undesirable interference effects to the pole-to-first-throw operation.

Although the foregoing example is described in the context of a single-pole-double-throw configuration, it will be understood that the RF core can be configured with other numbers of poles and throws. For example, there may be more than one poles, and the number of throws can be less than or greater than the example number of two.

In the example of FIG. 3, the transistors between the pole 102a and the two throw nodes 104a, 104b are depicted as single transistors. In some implementations, such switching functionalities between the pole(s) and the throw(s) can be provided by switch arm segments, where each switch arm segment includes a plurality of transistors such as FETs.

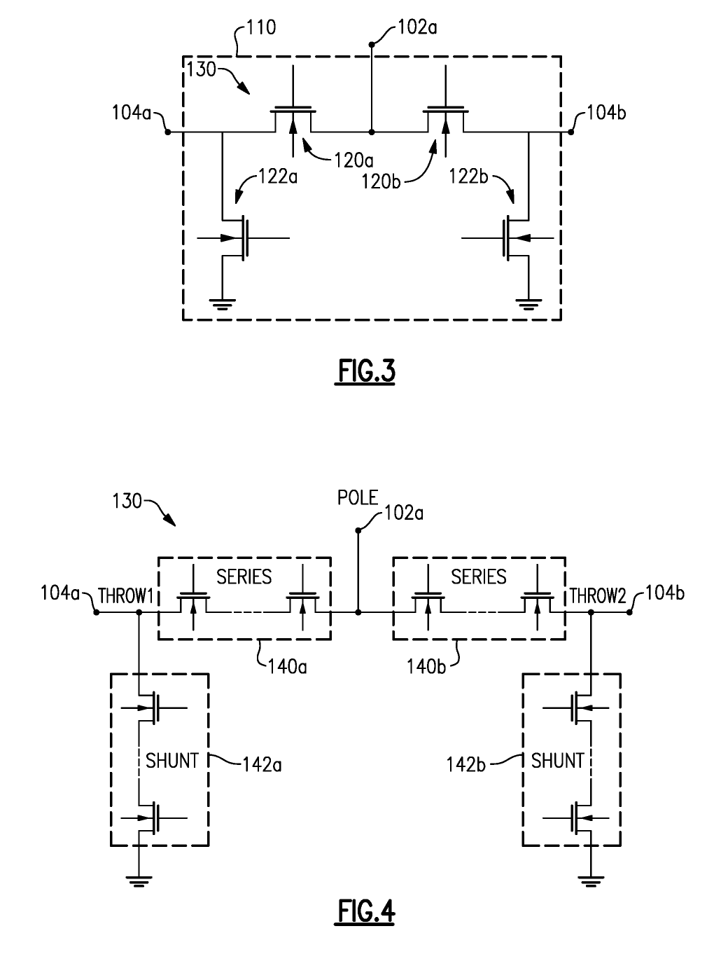

An example RF core configuration 130 of an RF core having such switch arm segments is shown in FIG. 4. In the example, the pole 102a and the first throw node 104a are shown to be coupled via a first switch arm segment 140a. Similarly, the pole 102a and the second throw node 104b are shown to be coupled via a second switch arm segment 140b. The first throw node 104a is shown to be capable of being shunted to an RF ground via a first shunt arm segment 142a. Similarly, the second throw node 104b is shown to be capable of being shunted to the RF ground via a second shunt arm segment 142b.

In an example operation, when the RF core 130 is in a state where an RF signal is being passed between the pole 102a and the first throw node 104a, all of the FETs in the first switch arm segment 140a can be in an ON state, and all of the FETs in the second switch arm segment 104b can be in an OFF state. The first shunt arm 142a for the first throw node 104a can have all of its FETs in an OFF state so that the RF signal is not shunted to ground as it travels from the pole 102a to the first throw node 104a. All of the FETs in the second shunt arm 142b associated with the second throw node 104b can be in an ON state so that any RF signals or noise arriving at the RF core 130 through the second throw node 104b is shunted to the ground so as to reduce undesirable interference effects to the pole-to-first-throw operation.

Again, although described in the context of an SP2T configuration, it will be understood that RF cores having other numbers of poles and throws can also be implemented.

In some implementations, a switch arm segment (e.g., 140a, 140b, 142a, 142b) can include one or more semiconductor transistors such as FETs. In some embodiments, an FET may be capable of being in a first state or a second state and can include a gate, a drain, a source, and a body (sometimes also referred to as a substrate. In some embodiments, an FET can include a metal-oxide-semiconductor field effect transistor (MOSFET). In some embodiments, one or more FETs can be connected in series forming a first end and a second end such that an RF signal can be routed between the first end and the second end when the FETs are in a first state (e.g., ON state).

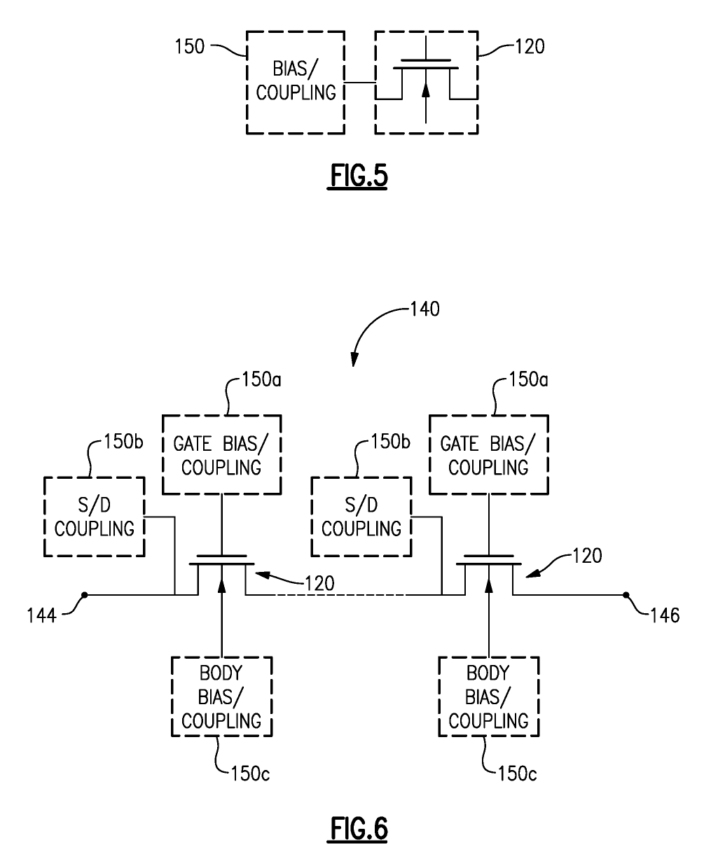

At least some of the present disclosure relates to how an FET or a group of FETs can be controlled to provide switching functionalities in desirable manners. FIG. 5 schematically shows that in some implementations, such controlling of an FET 120 can be facilitated by a circuit 150 configured to bias and/or couple one or more portions of the FET 120. In some embodiments, such a circuit 150 can include one or more circuits configured to bias and/or couple a gate of the FET 120, bias and/or couple a body of the FET 120, and/or couple a source/drain of the FET 120.

Schematic examples of how such biasing and/or coupling of different parts of one or more FETs are described in reference to FIG. 6. In FIG. 6, a switch arm segment 140 (that can be, for example, one of the example switch arm segments 140a, 140b, 142a, 142b of the example of FIG. 4) between nodes 144, 146 is shown to include a plurality of FETs 120. Operations of such FETs can be controlled and/or facilitated by a gate bias/coupling circuit 150a, and a body bias/coupling circuit 150c, and/or a source/drain coupling circuit 150b.

### Gate Bias/Coupling Circuit

In the example shown in FIG. 6, the gate of each of the FETs 120 can be connected to the gate bias/coupling circuit 150a to receive a gate bias signal and/or couple the gate to another part of the FET 120 or the switch arm 140. In some implementations, designs or features of the gate bias/coupling circuit 150a can improve performance of the switch arm 140. Such improvements in performance can include, but are not limited to, device insertion loss, isolation performance, power handling capability and/or switching device linearity. Example gate bias/coupling circuits are discussed in more detail in Appendix A.

### Body Bias/Coupling Circuit

As shown in FIG. 6, the body of each FET 120 can be connected to the body bias/coupling circuit 150c to receive a body bias signal and/or couple the body to another part of the FET 120 or the switch arm 140. In some implementations, designs or features of the body bias/coupling circuit 150c can improve performance of the switch arm 140. Such improvements in performance can include, but are not limited to, device insertion loss, isolation performance, power handling capability and/or switching device linearity. Example body bias/coupling circuits are discussed in more detail in Appendix A.

### Source/Drain Coupling Circuit

As shown in FIG. 6, the source/drain of each FET 120 can be connected to the coupling circuit 150b to couple the source/drain to another part of the FET 120 or the switch arm 140. In some implementations, designs or features of the coupling circuit 150b can improve performance of the switch arm 140. Such improvements in performance can include, but are not limited to, device insertion loss, isolation performance, power handling capability and/or switching device linearity. Example coupling circuits are discussed in more detail in Appendix A.

### Examples of Switching Performance Parameters:

Insertion Loss

A switching device performance parameter can include a measure of insertion loss. A switching device insertion loss can be a measure of the attenuation of an RF signal that is routed through the RF switching device. For example, the magnitude of an RF signal at an output port of a switching device can be less than the magnitude of the RF signal at an input port of the switching device. In some embodiments, a switching device can include device components that introduce parasitic capacitance, inductance, resistance, or conductance into the device, contributing to increased switching device insertion loss. In some embodiments, a switching device insertion loss can be measured as a ratio of the power or voltage of an RF signal at an input port to the power or voltage of the RF signal at an output port of the switching device. Decreased switching device insertion loss can be desirable to enable improved RF signal transmission.

Isolation

A switching device performance parameter can also include a measure of isolation. Switching device isolation can be a measure of the RF isolation between an input port and an output port an RF switching device. In some embodiments, it can be a measure of the RF isolation of a switching device while the switching device is in a state where an input port and an output port are electrically isolated, for example while the switching device is in an OFF state. Increased switching device isolation can improve RF signal integrity. In certain embodiments, an increase in isolation can improve wireless communication device performance.

Intermodulation Distortion

A switching device performance parameter can further include a measure of intermodulation distortion (IMD) performance. Intermodulation distortion (IMD) can be a measure of non-linearity in an RF switching device.

IMD can result from two or more signals mixing together and yielding frequencies that are not harmonic frequencies. For example, suppose that two signals have fundamental frequencies f₁ and f₂ (f₂>f₁) that are relatively close to each other in frequency space. Mixing of such signals can result in peaks in frequency spectrum at frequencies corresponding to different products of fundamental and harmonic frequencies of the two signals. For example, a second-order intermodulation distortion (also referred to as IMD2) is typically considered to include frequencies f₁+f₂ f₂−f₁, 2f₁, and 2f₂. A third-order IMD (also referred to as IMD3) is typically considered to include 2f₁+f₂, 2f₁−f₂, f₁₊₂f₂, f₁₋₂f₂. Higher order products can be formed in similar manners.

In general, as the IMD order number increases, power levels decrease. Accordingly, second and third orders can be undesirable effects that are of particular interest. Higher orders such as fourth and fifth orders can also be of interest in some situations.

In some RF applications, it can be desirable to reduce susceptibility to interference within an RF system. Non linearity in RF systems can result in introduction of spurious signals into the system. Spurious signals in the RF system can result in interference within the system and degrade the information transmitted by RF signals. An RF system having increased non-linearity can demonstrate increased susceptibility to interference. Non-linearity in system components, for example switching devices, can contribute to the introduction of spurious signals into the RF system, thereby contributing to degradation of overall RF system linearity and IMD performance.

In some embodiments, RF switching devices can be implemented as part of an RF system including a wireless communication system. IMD performance of the system can be improved by increasing linearity of system components, such as linearity of an RF switching device. In some embodiments, a wireless communication system can operate in a multi-band and/or multi-mode environment. Improvement in intermodulation distortion (IMD) performance can be desirable in wireless communication systems operating in a multi-band and/or multi-mode environment. In some embodiments, improvement of a switching device IMD performance can improve the IMD performance of a wireless communication system operating in a multi-mode and/or multi-band environment.

Improved switching device IMD performance can be desirable for wireless communication devices operating in various wireless communication standards, for example for wireless communication devices operating in the LTE communication standard. In some RF applications, it can be desirable to improve linearity of switching devices operating in wireless communication devices that enable simultaneous transmission of data and voice communication. For example, improved IMD performance in switching devices can be desirable for wireless communication devices operating in the LTE communication standard and performing simultaneous transmission of voice and data communication (e.g., SVLTE).

High Power Handling Capability

In some RF applications, it can be desirable for RF switching devices to operate under high power while reducing degradation of other device performance parameters. In some embodiments, it can be desirable for RF switching devices to operate under high power with improved intermodulation distortion, insertion loss, and/or isolation performance.

In some embodiments, an increased number of transistors can be implemented in a switch arm segment of a switching device to enable improved power handling capability of the switching device. For example, a switch arm segment can include an increased number of FETs connected in series, an increased FET stack height, to enable improved device performance under high power. However, in some embodiments, increased FET stack height can degrade the switching device insertion loss performance.

### Examples of FET Structures and Fabrication Process Technologies:

A switching device can be implemented on-die, off-die, or some combination thereon. A switching device can also be fabricated using various technologies. In some embodiments, RF switching devices can be fabricated with silicon or silicon-on-insulator (SOI) technology.

As described herein, an RF switching device can be implemented using silicon-on-insulator (SOI) technology. In some embodiments, SOI technology can include a semiconductor substrate having an embedded layer of electrically insulating material, such as a buried oxide layer beneath a silicon device layer. For example, an SOI substrate can include an oxide layer embedded below a silicon layer. Other insulating materials known in the art can also be used.

Implementation of RF applications, such as an RF switching device, using SOI technology can improve switching device performance. In some embodiments, SOI technology can enable reduced power consumption. Reduced power consumption can be desirable in RF applications, including those associated with wireless communication devices. SOI technology can enable reduced power consumption of device circuitry due to decreased parasitic capacitance of transistors and interconnect metallization to a silicon substrate. Presence of a buried oxide layer can also reduce junction capacitance or use of high resistivity substrate, enabling reduced substrate related RF losses. Electrically isolated SOI transistors can facilitate stacking, contributing to decreased chip size.

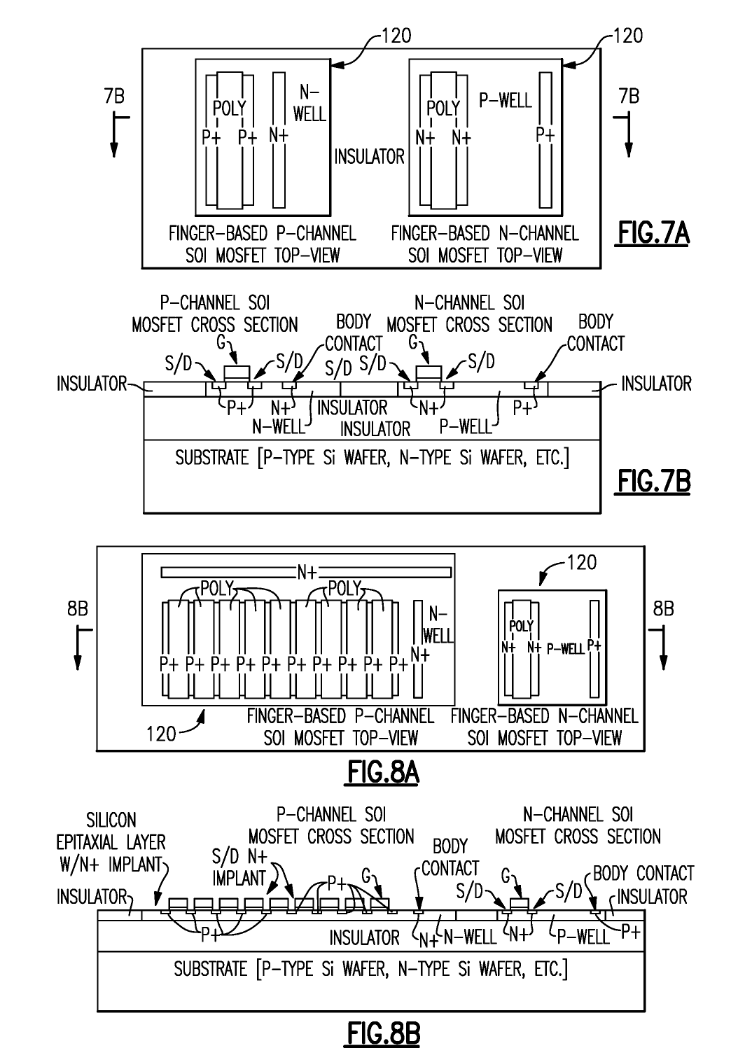

In some SOI FET configurations, each transistor can be configured as a finger-based device where the source and drain are rectangular shaped (in a plan view) and a gate structure extends between the source and drain like a rectangular shaped finger. FIGS. 7A and 7B show plan and side sectional views of an example finger-based FET device implemented on SOI. As shown, FET devices described herein can include a p-type FET or an n-type FET. Thus, although some FET devices are described herein as p-type devices, it will be understood that various concepts associated with such p-type devices can also apply to n-type devices.

As shown in FIGS. 7A and 7B, a pMOSFET can include an insulator layer formed on a semiconductor substrate. The insulator layer can be formed from materials such as silicon dioxide or sapphire. An n-well is shown to be formed in the insulator such that the exposed surface generally defines a rectangular region. Source (S) and drain (D) are shown to be p-doped regions whose exposed surfaces generally define rectangles. As shown, S/D regions can be configured so that source and drain functionalities are reversed.

FIGS. 7A and 7B further show that a gate (G) can be formed on the n-well so as to be positioned between the source and the drain. The example gate is depicted as having a rectangular shape that extends along with the source and the drain. Also shown is an n-type body contact. Formations of the rectangular shaped well, source and drain regions, and the body contact can be achieved by a number of known techniques. In some embodiments, the source and drain regions can be formed adjacent to the ends of their respective upper insulator layers, and the junctions between the body and the source/drain regions on the opposing sides of the body can extend substantially all the way down to the top of the buried insulator layer. Such a configuration can provide, for example, reduced source/drain junction capacitance. To form a body contact for such a configuration, an additional gate region can be provided on the side so as to allow, for example, an isolated P+ region to contact the Pwell.

FIGS. 8A and 8B show plan and side sectional views of an example of a multiple-finger FET device implemented on SOI. Formations of rectangular shaped n-well, rectangular shaped p-doped regions, rectangular shaped gates, and n-type body contact can be achieved in manners similar to those described in reference to FIGS. 7A and 7B.

The example multiple-finger FET device of FIGS. 8A and 8B can be made to operate such that a drain of one FET acts as a source of its neighboring FET. Thus, the multiple-finger FET device as a whole can provide a voltage-dividing functionality. For example, an RF signal can be provided at one of the outermost p-doped regions (e.g., the leftmost p-doped region); and as the signal passes through the series of FETs, the signal's voltage can be divided among the FETs. In such an example, the rightmost p-doped region can act as an overall drain of the multi-finger FET device.

In some implementations, a plurality of the foregoing multi-finger FET devices can be connected in series as a switch to, for example, further facilitate the voltage-dividing functionality. A number of such multi-finger FET devices can be selected based on, for example, power handling requirement of the switch.

Examples of Bias and/or Coupling Configurations for Improved Performance:

Described herein are various examples of how FET-based switch circuits can be biased and/or coupled to yield one or more performance improvements. In some embodiments, such biasing/coupling configurations can be implemented in SOI FET-based switch circuits. It will be understood that some of the example biasing/coupling configurations can be combined to yield a combination of desirable features that may not be available to the individual configurations. It will also be understood that, although described in the context of RF switching applications, one or more features described herein can also be applied to other circuits and devices that utilize FETs such as SOI FETs.

### Example Configurations

Switches (such as FETs) may generally operate using a negative voltage. For example, the gate of a switch may be biased with a positive voltage (e.g., 2.5 volts (V)) and the drain, source, and body may be biased with a substantially zero voltage, when the switch is ON (e.g., is in an ON state). The gate and body may be biased with a negative voltage (e.g., −2.5V) and the drain and source may be biased with a substantially zero voltage, when the switch is OFF (e.g., is in an OFF state).

Voltage swings may cause the gate oxide of a switch to break down and may affect the reliability of the switch. Large voltage swings may also cause C_{OFF} to be more non-linear and may turn on diodes in the switch. A negative voltage generator (NVG) may be used to generate the negative voltage used by the switch. The NVG may help keep the off-capacitance (C_{OFF}) of the switch more linear when there is a voltage swing in the switch. However, the NVG may include an oscillator, a charge pump, and filters, which consume a larger die area and may also consume more power. The NVG may also cause clock feedthrough issues and may introduce spurious signals into a system (e.g., a RF circuit, a RF module, a RF system, etc.).

In many radio-frequency (RF) applications, it is desirable to utilize switches having high linearity. As described herein, such advantageous performance features can be achieved without significantly degrading reliability of RF switches.

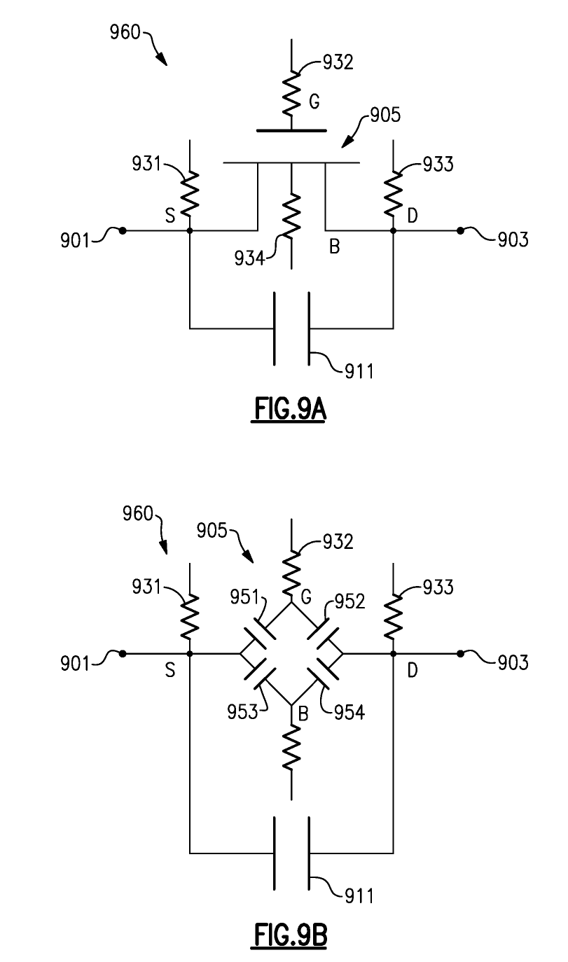

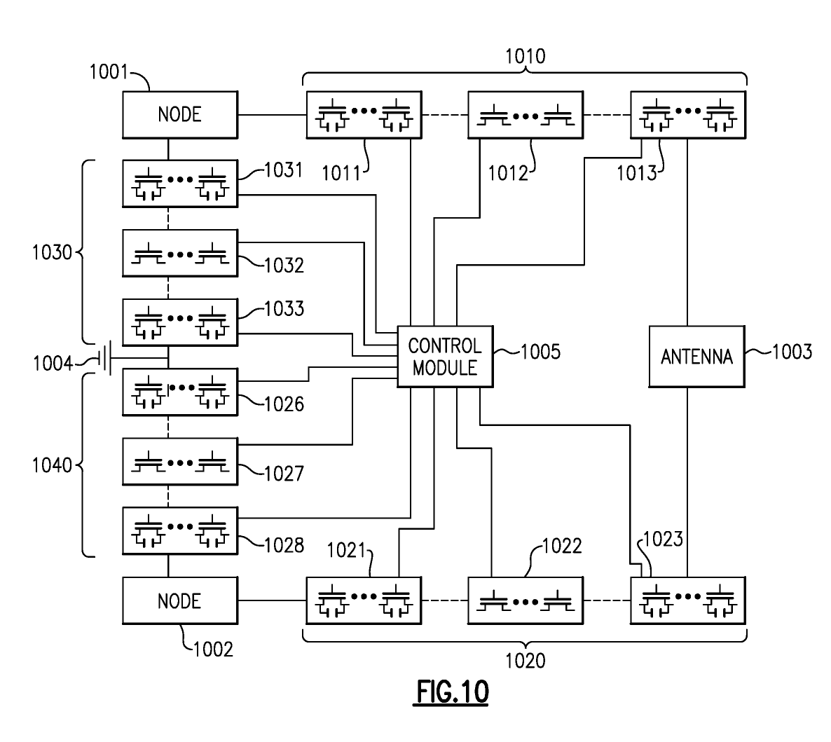

FIG. 9A is a diagram illustrating an example switch circuit 960 disposed between a first node 901 and a second node 903, in accordance with some embodiments of the present disclosure. The switch circuit 960 may be configured to provide switching functionality between the first node 901 and the second node 903. In one embodiment, the FET 905 may be an SOI FET (as illustrated and discussed above. The switch circuit 960 includes a FET 905 and a capacitance 911. The FET 905 includes a source S, a gate G, a body B and a drain D. The source S is coupled to the first node 901 and the drain D is coupled to the second node 903. In one embodiment, the first node 901 may be an input node and may receive a signal, such as an RF signal. The second node 903 may be an output node and may output the signal (such as an RF signal). The FET 905 may output the signal (received at the source G from the first node 901) via the drain D (to the second node 903) when the first FET 905 is in an ON state. The FET 905 may prevent (may stop) a signal (received at the source G from the first node 901) from being outputted via the drain D (to the second node 903) when the first FET 905 is in an OFF state.

In one embodiment, the FET 905 is coupled in parallel with a capacitance 911 (e.g., a capacitor). The capacitance 911 may be coupled to the source S and the drain D (as illustrated in FIG. 9A). The capacitance 911 may also be coupled to the first node 901 and the second node 903. In one embodiment, the capacitance 911 may be a switchable capacitor. A switchable capacitor may be a capacitor that may turned ON or OFF. In one embodiment, the switchable capacitor (e.g., capacitance 911) may be ON when the FET 905 is ON. When the switchable capacitor is ON, the switchable capacitor may pass the signal (e.g., an RF signal) received from the first node 901 to the second node 903. In another embodiment, the switchable capacitor may be OFF when the FET 905 is OFF. When the switchable capacitor is OFF, the switchable capacitor may act, operate, and/or function as a direct current (DC) blocker (e.g., may block a DC signal/current). In one embodiment, the switchable capacitor may be turned ON (e.g., may be ON, may be in an ON state), when the FET is ON (e.g., turn ON or in an ON state. In another embodiment, the switchable capacitor may be turned OFF (e.g., may be OFF, may be in an OFF state), when the FET is OFF (e.g., turn OFF or in an OFF state. In one embodiment, the capacitance 911 may be a metal-insulator-metal (MIM) capacitor.

In one embodiment, the FET 905 may operate without using a negative voltage. For example, the FET 907 may operating without using a negative voltage to bias the gate G and the body B. In one embodiment, the gate G may be biased with a positive voltage (e.g., 2.5 volts (V)), and the drain D, source S, and body B may be biased with a substantially zero voltage when the FET 905 is turned ON. In another embodiment, the drain D and the source S may be biased with a positive voltage (e.g., 2.1V), and the body and the gate may be biased with a substantially zero voltage when the FET 905 is turned OFF. The source S may receive a source bias voltage (Vₛ) via a resistance 931 (e.g., a resistor), the drain D may receive a drain bias voltage (V_{d}) via a resistance 933, the gate may receive a gate bias voltage (V_{g}) via a resistance 932, and the body may receive a body bias voltage (V_{b}) via a resistance 934. One having ordinary skill in the art understands that the voltages described herein (e.g., 2.1V, 2.5V) are merely examples and that other voltages may be used to bias the source S, drain D, gate G, and/or body B.

In one embodiment, the switch circuit 960 may be coupled to one or more additional FETs (e.g., a set of FETs) in series, as discussed in more detail below. The one or more additional FETs may be coupled to each other in series. The number of additional FETS may be selected to allow the RF switch to handle a power of the RF signal (e.g., may be selected based on a power handling requirement).

In some embodiments, the switches, switch circuits, switch arms, and/or switch arm segments may prevent or reduce parasitic junction diodes being turned on, and can reduce distortions associated with large voltage swings. In other embodiments, the switches, switch circuits, switch arms, and/or switch arm segments may improve the linearity of switches, switch circuits, switch arms, and/or switch arm segments. In some embodiments, the switches, switch circuits, switch arms, and/or switch arm segments may operate without using a NVG. This may allow modules, components, and/or devices to use less space (e.g., to be smaller) and consume less power. This may also reduce clock feedthrough issues and may help reduce the spurious signals from introduced into the system. In one embodiment, the switches, switch circuits, switch arms, and/or switch arm segments may operate using positive voltages only. For example, the switches, switch circuits, switch arms, and/or switch arm segments may operator without using negative voltages. In some embodiments, the switches, switch circuits, switch arms, and/or switch arm segments may maintain good linearity without using a NVG.

In some embodiments, the resistances 931, 932, and 933, the FET 905, and the capacitance 911 may be implemented on the same die (e.g., the same semiconductor die). In other embodiments, the resistances 931, 932, and 933, the FET 905, and the capacitance 911 may be implemented across a plurality of dies.

In some embodiments, the switch circuit 960 may also include one or more coupling circuits (as discussed in more detail in Appendix A). For example, a coupling circuit (discussed in more detail in Appendix A)) may be coupled to the body B of the FET 905.

FIG. 9B is a diagram illustrating example capacitances between components of the example switch circuit 960 illustrated in FIG. 9A, in accordance with some embodiments of the present disclosure. As discussed above, the switch circuit includes a FET 905 and the FET 905 includes a source S, a gate G, a body B and a drain D. The source S may receive a source bias voltage (Vₛ) via a resistance 931 (e.g., a resistor), the drain D may receive a drain bias voltage (V_{d}) via a resistance 933, the gate may receive a gate bias voltage (V_{g}) via a resistance 932, and the body may receive a body bias voltage (V_{b}) via a resistance 934. A capacitance 911 is coupled in parallel with the FET 905.

Capacitance 951 represents the parasitic capacitance between the source S and the gate G of the FET 905. Capacitance 952 represents the parasitic capacitance between the gate G and the drain D. Capacitance 953 represents the parasitic capacitance between source S and the body B. Capacitance 954 represents the parasitic capacitance between the body B and the drain D.

The capacitance 953 may be linear when voltage swings occur in the switch circuit 960 and the capacitance 954 may be non-linear when voltage swings occur in the switch circuit 960. In one embodiment, the capacitance 911 (which is coupled in parallel with the FET 905, as illustrated in FIGS. 9A and 9B) may help the capacitance 954 remain linear (or more linear) when voltage swings occur in the switch circuit 960. For example, the capacitance 911 may lower the amount of AC swing on the switch circuit 960 (e.g., on the FET 905) and this may help keep the capacitance 954 remain linear (or more linear).

FIG. 10 is a diagram illustrating example switch arms 1010 1020, 1030, and 1040, in accordance with some embodiments of the present disclosure. The switch arms 1010 1020, 1030, and 1040 may be included in an RF core that may be configured to route RF signals between two ports or nodes (e.g., RF core 110 illustrated in FIGS. 2 and 3). Switch arm 1010 is coupled to a first node 1001 (e.g., an RF node that may supply an RF signal to the switch arm 1010) and an antenna 1003. Switch arm 1020 is coupled to a second node 1002 (e.g., an RF node that may supply an RF signal to the switch arm 1020) and the antenna 1003. Switch arm 1030 is coupled to the first node 1001 and ground 1004. Switch arm 1040 is coupled to the second node 1002 and ground 1004. Control module 1005 is coupled to switch arm segments 1011, 1012, 1013, 1021, 1022, 1023, 1031, 1032, 1033, 1041, 1042, and 1043.

Switch arm 1010 includes switch arm segments 1011, 1012, and 1013. Switch arm 1020 includes switch arm segments 1021, 1022, and 1023. Switch arm 1030 includes switch arm segments 1031, 1032, and 1033. Switch arm 1040 includes switch arm segments 1041, 1042, and 1043. Switch arm segments 1011, 1013, 1021, 1023, 1031, 1033, 1041, and 1043 may each include one or more (e.g., a set) of switch circuit 960 illustrated in FIG. 9A. The one or more switch circuits (e.g., one or more switch circuits 960) may be coupled in series. Switch arm segments 1012, 1022, 1032, and 1042 may each include one or more FETs (or other types of switches). The number of FETS in the switch arm segments 1012, 1022, 1032, and 1042 may be selected to allow a respective switch arm (e.g., switch arm 1010, 1020, 1030, and/or 1040) to handle the power of the RF signal (e.g., may be selected based on a power handling requirement). In one embodiment, the switch arm 1030 may provide shunting capability for the first node 1001 and the switch arm 1040 may provide shunting capability for second node 1002 (as discussed above).

The switch arms 1010, 1020, 1030, and 1040 may be turned ON or OFF by turning the FETs and/or switch circuits (e.g., switch circuit 960 illustrated in FIG. 9A) ON or OFF. For example, the switch arm 1010 may be ON when the FETs in switch arm segment 1012 and the switch circuits in switch arm segments 1011 and 1013 are ON. In another example, the switch arm 1030 may be OFF when the FETs in the switch arm segment 1032 and the switch circuits in the switch arm segments 1031 and 1033 are OFF.

In one embodiment, a signal received via node 1001 (e.g., a low-band RF signal) may be provided to the antenna 1003 when the switch arms 1010 and 1040 are ON, and the switch arms 1020 and 1030 are OFF.

In another embodiment, the signal received via node 1002 may be provided to the antenna 1003 when the 1003 when the switch arms 1020 and 1030 are ON, and the switch arms 1010 and 1040 are OFF.

In one embodiment, the control module 1005 may turn the switch arm segments 1011, 1012, 1013, 1021, 1022, 1023, 1031, 1032, 1033, 1041, 1042, and/or 1043, ON or OFF. For example, the control module 1005 may cause bias voltages to be supplied/provided to the sources, drains, bodies, or gates of the FETs in the switch arm segments 1012, 1022, 1032, and/or 1042. In another example, the control module 1005 may turn switchable capacitors ON or OFF, and may cause bias voltages to be supplied/provided to the sources, drains, bodies, or gates of the FETs in the switch arm segments 1011, 1013, 1021, 1023, 1031, 1033, 1041, and 1043. The control module 1005 may be hardware (e.g., circuitry, dedicated logic, programmable logic, microcode, a processor, a field-programmable gate array (FPGA), an application-specific integrated circuit (ASIC), etc.), software (e.g., instructions run on a processor, firmware, or a combination thereof.

In some embodiments, and as described herein, the foregoing example configurations described in reference to FIGS. 9A, 9B, and 10 can be relatively simpler and easier to implement, and can yield a number of improvements. For example, some embodiments may help prevent or reduce parasitic junction diodes being turned on, and can reduce distortions associated with large voltage swings. In another example, other embodiments may improve the linearity of switches, switch circuits, switch arms, and/or switch arm segments.

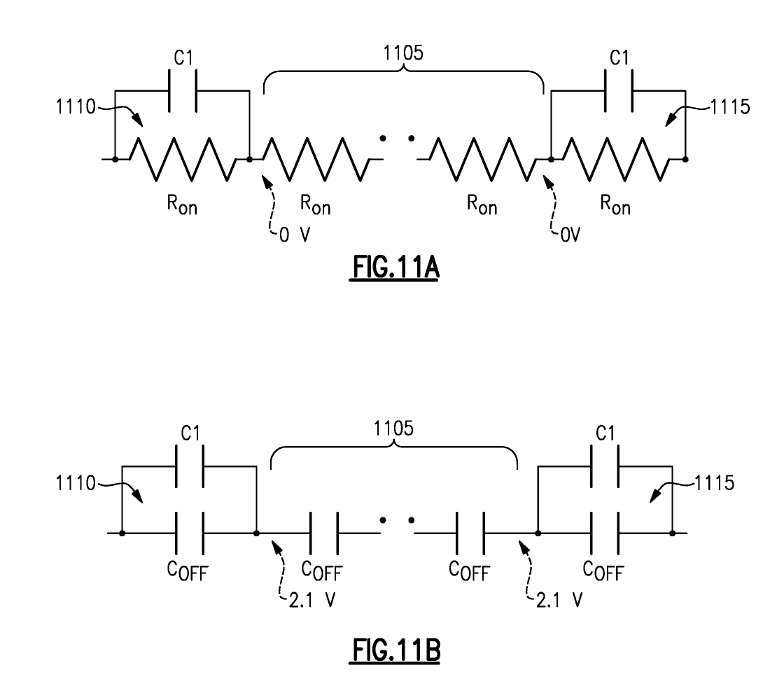

FIG. 11A is diagram illustrating an example first order model of an example switch arm. For example, the first order model may be for one of the switch arms 1010, 1020, 1030, or 1050 illustrated in FIG. 10. The example switch arm includes a set of FETs 1105 coupled between two switch circuits 1105 and 1110 (e.g., coupled between two switch circuits 900, illustrated in FIG. 9A). Each switch circuit includes a FET and a capacitance C1 (as discussed above). The capacitances C1 may be switchable capacitors, as discussed above. The set of FETs may include any number of FETs coupled in series (e.g., may include twelve FETs coupled in series, may include twenty FETs coupled in series, etc.).

In one embodiment, the switch arm (e.g., switch arm 1010) may be in ON (e.g., may be in an ON state). As discussed above, the switch arm may be ON when the set of FETs 1105 and the switch circuits 1110 and 1115 in switch arm are ON. Also as discussed above, the capacitances C1 may be ON (e.g., the switchable capacitors may be ON) when the switch circuits 1110 and 1115 are ON. The capacitances C1 may pass through a signal (received via the source of the switch circuit 1105) when the capacitance C1 is ON. Each of the FETs (e.g., the FETs in the set of FETs 1105 and the FETs in the switch circuits 1110 and 1115) has a resistance RON when the FETs are ON (e.g., in an ON state). When the switch arm is ON, the gate of each FET may be biased with a positive voltage (such as 2.5V) and the body, drain, and source of each FET may be biased with a substantially zero voltage. A substantially zero voltage may also be applied to the connections (e.g., wires, pins, traces, leads, etc.) between the switch circuits 1110 and 1115, and the set of FETs 1105 (as illustrated by the dashed arrows in FIG. 11A).

FIG. 11B is diagram illustrating an example first order model of an example switch arm. For example, the first order model may be for one of the switch arms 1010, 1020, 1030, or 1050 illustrated in FIG. 10. The example switch arm includes a set of FETs 1105 coupled between two switch circuits 1105 and 1110 (e.g., coupled between two switch circuits 900, illustrated in FIG. 9A). Each switch circuit includes a FET and a capacitance C1 (as discussed above). The capacitances C1 may be switchable capacitors, as discussed above. The set of FETs may include any number of FETs coupled in series (e.g., may include twelve FETs coupled in series, may include twenty FETs coupled in series, etc.).

In one embodiment, the switch arm (e.g., switch arm 1010) may be in OFF (e.g., may be in an OFF state). As discussed above, the switch arm may be OFF when the set of FETs 1105 and the switch circuits 1110 and 1115 in switch arm are OFF. Also as discussed above, the capacitances C1 may be OFF (e.g., the switchable capacitors may be OFF) when the switch circuits 1110 and 1115 are OFF. The capacitances C1 may function, act, and/or operate as a DC blocker (e.g., may block a DC signal) when the capacitances C1 are OFF.

Each of the FETs (e.g., the FETs in the set of FETs 1105 and the FETs in the switch circuits 1110 and 1115) has an off-capacitance C_{OFF} when the FETs are OFF (e.g., in an OFF state). Swings (e.g., voltage swings) in the signal received by the switch arm may be distributed through the C_{OFF} stack (e.g., through the switch arm) when the switch arm is OFF.

When switch arm is OFF, the drain and source of each FET in the set of FETs 1105 may be may be biased with a positive voltage, such as 2.1V, and the gate and the body of each FET in the set of FETs 1105 may be may be biased with a substantially zero voltage. In addition, when the switch arm is OFF, the drain of each of the switch circuits 1110 and 1115 may be biased with a positive voltage (e.g., 2.1V), and the source, gate, and body of each of the switch circuits 1110 and 1115 may be biased with a substantially zero voltage. A voltage of 2.1V may also be applied to the connections (e.g., wires, pins, traces, leads, etc.) between the switch circuits 1110 and 1115, and the set of FETs 1105 (as illustrated by the dashed arrows in FIG. 11B).

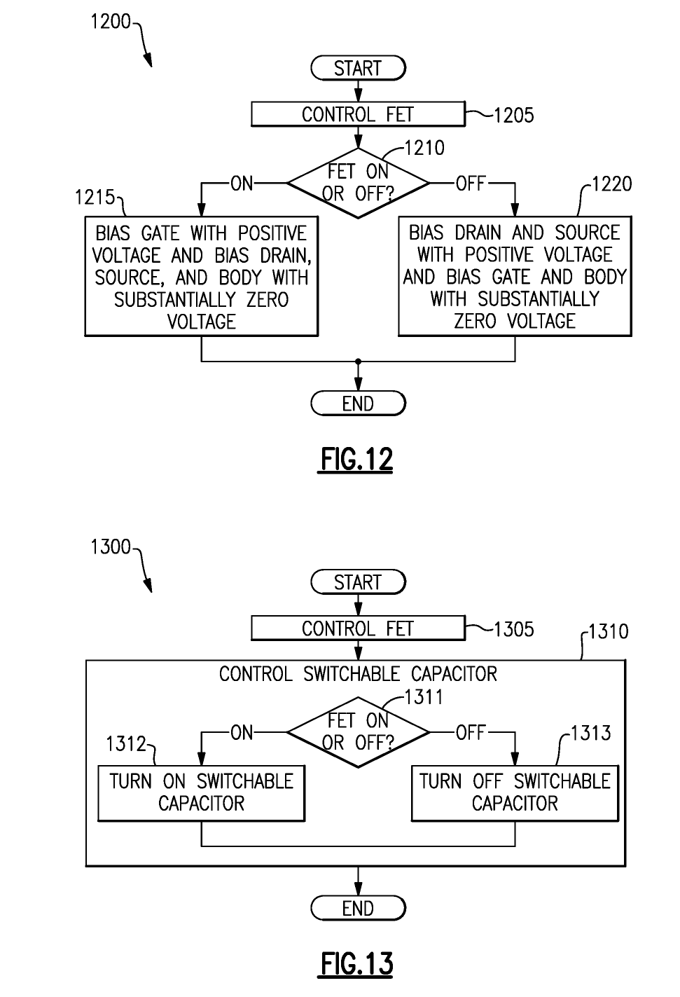

FIG. 12 is a flow diagram illustrating process 1200 for operating a switch (e.g., a FET or a switch circuit, such as switch circuit 900 illustrated in FIG. 9A), according to some embodiments of the present disclosure. The process 1200 may be performed by processing logic that comprises hardware (e.g., circuitry, dedicated logic, programmable logic, microcode, a processor, a FPGA, an ASIC, etc.), software (e.g., instructions run on a processor), firmware, or a combination thereof. In one embodiment, process 1200 may be performed by a control module (as illustrated in FIG. 10). In addition, the process 1200 could alternatively be represented as a series of interrelated states via a state diagram or events. In some embodiments, the process 1200 may be at least partially performed by a processor executing code stored in a non-transitory computer-readable medium (e.g., a memory).

The process 1200 begins at block 1205 where the process 1200 controls a first FET (or switch) disposed between a first node and a second node. For example, the FET may be controlled such that the FET is in an ON state (e.g., is ON) or is in an OFF state (e.g., is OFF). At block 1210, the process 1200 determines whether the FET is in an ON state or an OFF state. If the FET is in an ON state, the process 1200 may bias a gate of the first FET with a first positive voltage and may bias a drain, a source, and a body of the first FET with a substantially zero voltage, at block 1215. If the FET is in an OFF state, the process 1200 may bias the drain and the source of the first FET with a first positive voltage and may bias the gate and the body of the first FET with a substantially zero voltage, at block 1215, at block 1220.

FIG. 13 is a flow diagram illustrating process 1300 for operating a switch (e.g., a FET or a switch circuit, such as switch circuit 900 illustrated in FIG. 9A), according to some embodiments of the present disclosure. The process 1300 may be performed by processing logic that comprises hardware (e.g., circuitry, dedicated logic, programmable logic, microcode, a processor, a FPGA, an ASIC, etc.), software (e.g., instructions run on a processor), firmware, or a combination thereof. In one embodiment, process 1300 may be performed by a control module (as illustrated in FIG. 10). In addition, the process 1300 could alternatively be represented as a series of interrelated states via a state diagram or events. In some embodiments, the process 1300 may be at least partially performed by a processor executing code stored in a non-transitory computer-readable medium (e.g., a memory).

The process 1300 begins at block 1305 where the process 1300 controls a first FET (or switch) disposed between a first node and a second node. For example, the FET may be controlled such that the FET is in an ON state (e.g., is ON) or is in an OFF state (e.g., is OFF). At block 1310, the process 1300 may control the switchable capacitor. For example, the switchable capacitor may be controlled such that the switchable capacitor is in an ON state (e.g., is ON) or is in an OFF state (e.g., is OFF).

Block 130 includes blocks 1311, 1312, and 1313. The process 1300 determines whether the FET is in an ON state or an OFF state at block 1311. If the FET is in an ON state, the process 1300 may turn ON the switchable capacitor (e.g., may change the switchable capacitor to an ON state) at block 1312. If the FET is in an OFF state, the process 1300 may turn OFF the switchable capacitor (e.g., may change the switchable capacitor to an OFF state) at block 1313.

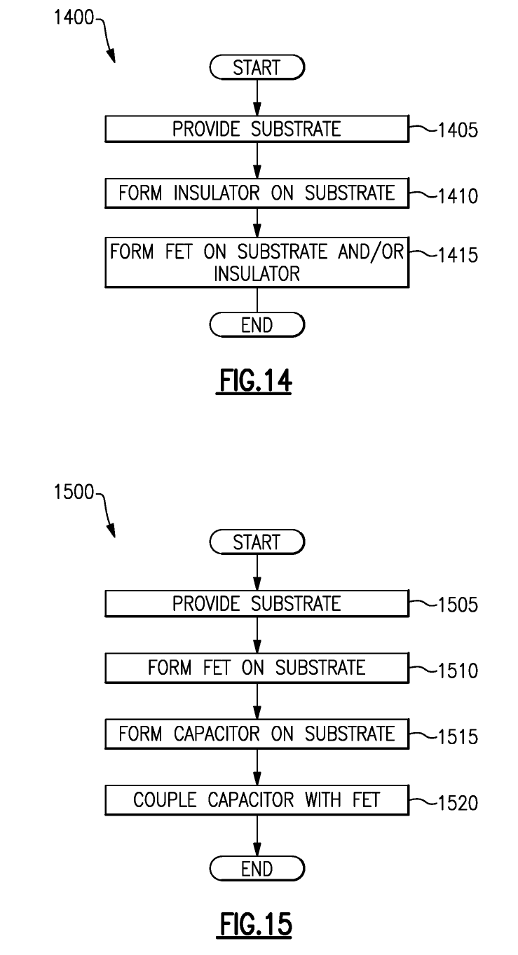

FIG. 14 is a flow diagram illustrating process 1400 for fabricating a switch (e.g., a FET or a switch circuit, such as switch circuit 900 illustrated in FIG. 9A) having one or more features as described herein, according to some embodiments of the present disclosure. The process 1400 may be performed by processing logic that comprises hardware (e.g., circuitry, dedicated logic, programmable logic, microcode, a processor, a FPGA, an ASIC, etc.), software (e.g., instructions run on a processor), firmware, or a combination thereof. In addition, the process 1400 could alternatively be represented as a series of interrelated states via a state diagram or events. In some embodiments, the process 1400 may be at least partially performed by a processor executing code stored in a non-transitory computer-readable medium (e.g., a memory).

The process 1400 begins at block 1405 where the process 1400 provides a substrate. For example, a semiconductor substrate and/or a packaging substrate may be provided. At block 1410, the process 1400 may optionally form an insulator on the substrate, as discussed above. The process 1400 may form a FET on the substrate and/or the insulator (if the optional block 1410 is performed) at block 1415.

FIG. 15 is a flow diagram illustrating process 1500 for fabricating a switch (e.g., a FET or a switch circuit, such as switch circuit 900 illustrated in FIG. 9A) having one or more features as described herein, according to some embodiments of the present disclosure. The process 1500 may be performed by processing logic that comprises hardware (e.g., circuitry, dedicated logic, programmable logic, microcode, a processor, a FPGA, an ASIC, etc.), software (e.g., instructions run on a processor), firmware, or a combination thereof. In addition, the process 1500 could alternatively be represented as a series of interrelated states via a state diagram or events. In some embodiments, the process 1500 may be at least partially performed by a processor executing code stored in a non-transitory computer-readable medium (e.g., a memory).

The process 1500 begins at block 1505 where the process 1500 provides a substrate. For example, a semiconductor substrate and/or a packaging substrate may be provided. At block 1510, the process 1500 may optionally form an insulator on the substrate, as discussed above. The process 1500 may also optionally form an insulator on the substrate, as discussed above. The process 1500 may form a FET on the substrate at block 1510. At block 1515, the process 1500 may form a capacitor on the substrate. The capacitor may be a switchable capacitor, as discussed above. The process 1500 may couple the capacitor (e.g., the switchable capacitor) with the FET at block 1520. The FET and the capacitor may be coupled in parallel, as discussed above.

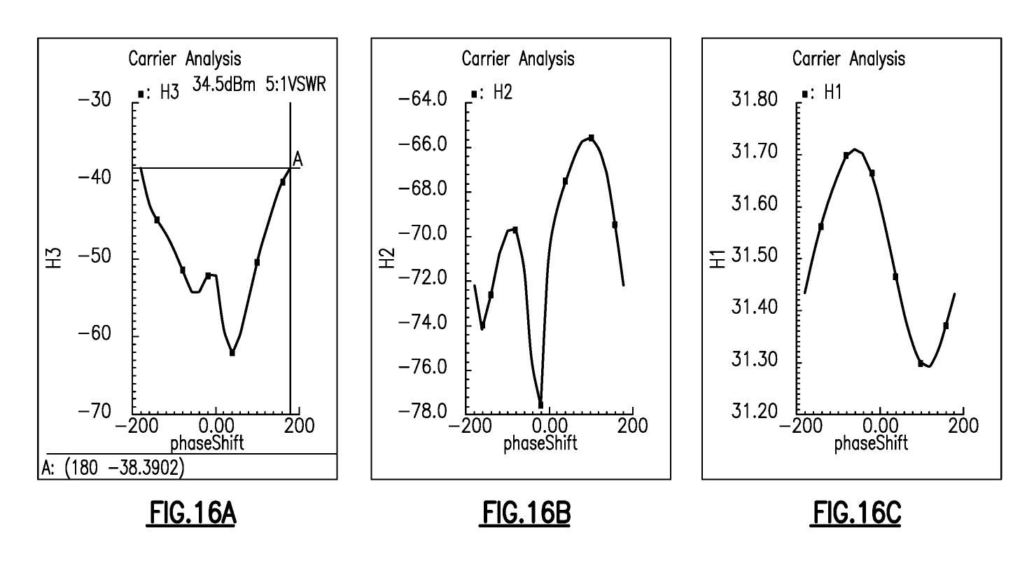

FIGS. 16A-16C illustrate harmonics related performance examples for the switches, switch circuits (e.g., switch circuit 900 illustrated in FIG. 9A), switch arms (e.g., switch arm 1010 illustrated in FIG. 10), and/or switch arm segments described herein (e.g., switch arm segments 1011, 1012, and 1013, illustrated in FIG. 10). More particularly, FIGS. 16A-16C illustrate harmonics plots as a function of phase shift. In each of FIGS. 16A-16C, the voltage standing wave ratio (VSWR) is approximately 5 (e.g., 5:1) and the input power is approximately 34.5 dBm.

FIG. 16A illustrates first order harmonics (H1) plotted as a function of phase shift. FIG. 16B illustrates second order harmonics (H2) plotted as a function of phase shift. FIG. 16C illustrates third order harmonics (H3) are plotted as a function of phase shift.

Based on the foregoing examples, it is noted that harmonics related performance remains good and/or is not significantly degraded when the switches, switch circuits (e.g., switch circuit 900 illustrated in FIG. 9A), switch arms (e.g., switch arm 1010 illustrated in FIG. 10), and/or switch arm segments described herein are implemented. As described herein, such switches, switch circuits, switch arms, and/or switch arm segments may provide a number of advantageous features.

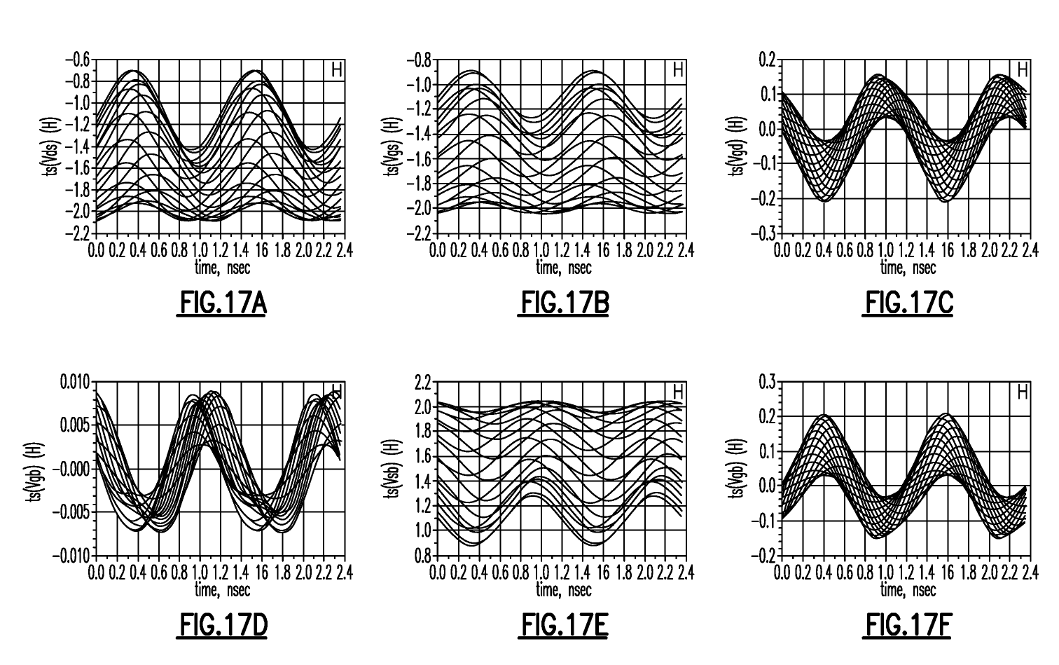

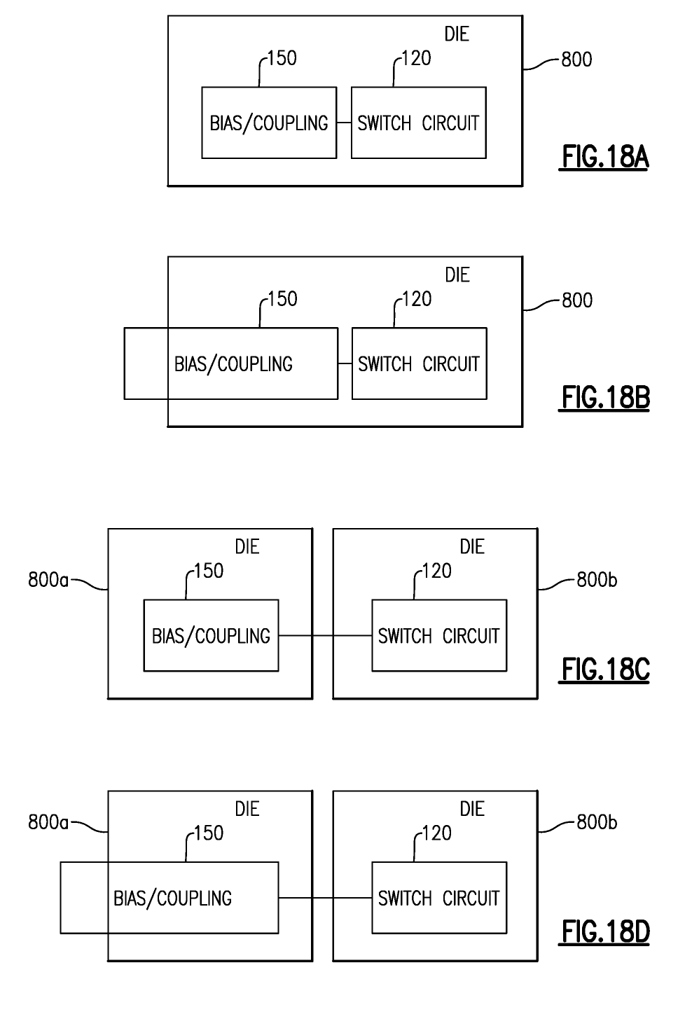

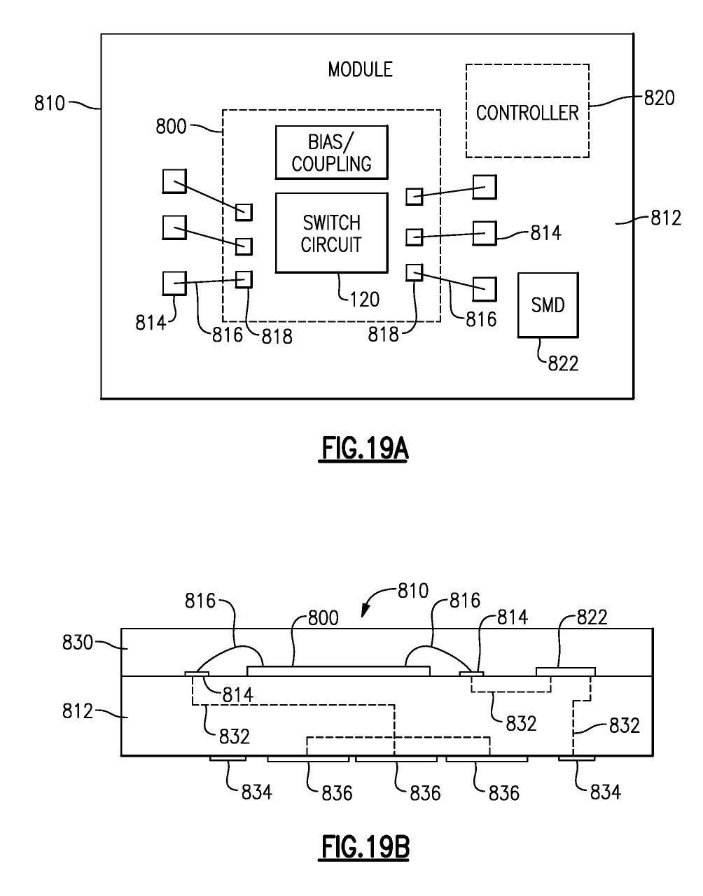

FIGS. 17A-17F illustrate example voltages between different components, portions, and/or sections of the switches, switch circuits (e.g., switch circuit 900 illustrated in FIG. 9A), switch arms (e.g., switch arm 1010 illustrated in FIG. 10), and/or switch arm segments described herein (e.g., switch arm segments 1011, 1012, and 1013, illustrated in FIG. 10). More particularly, FIGS. 17A-17F illustrate example voltage swings between different components, portions, and/or sections of switches, switch circuits, switch arms, and/or switch arm segments when the phase (e.g., phase offset) of an input signal is varied. In each of FIGS. 17A-17F, power of the input signal is approximately 35 dBm.

FIG. 17A illustrates example voltage swings (e.g., variations in voltage) between a drain and a source for different phases of the input signal. FIG. 17B illustrates example voltage swings (e.g., variations in voltage) between a gate and the source for different phases of the input signal. FIG. 17C illustrates example voltage swings (e.g., variations in voltage) between the gate and the drain for different phases of the input signal. FIG. 17D illustrates example voltage swings (e.g., variations in voltage) between the gate and a body for different phases of the input signal. FIG. 17E illustrates example voltage swings (e.g., variations in voltage) between the source and the body for different phases of the input signal. FIG. 17F illustrates example voltage swings (e.g., variations in voltage) between the drain and the body for different phases of the input signal.

### Examples of Implementations in Products:

Various examples of FET-based switch circuits and bias/coupling configurations described herein can be implemented in a number of different ways and at different product levels. Some of such product implementations are described by way of examples.

### Semiconductor Die Implementation

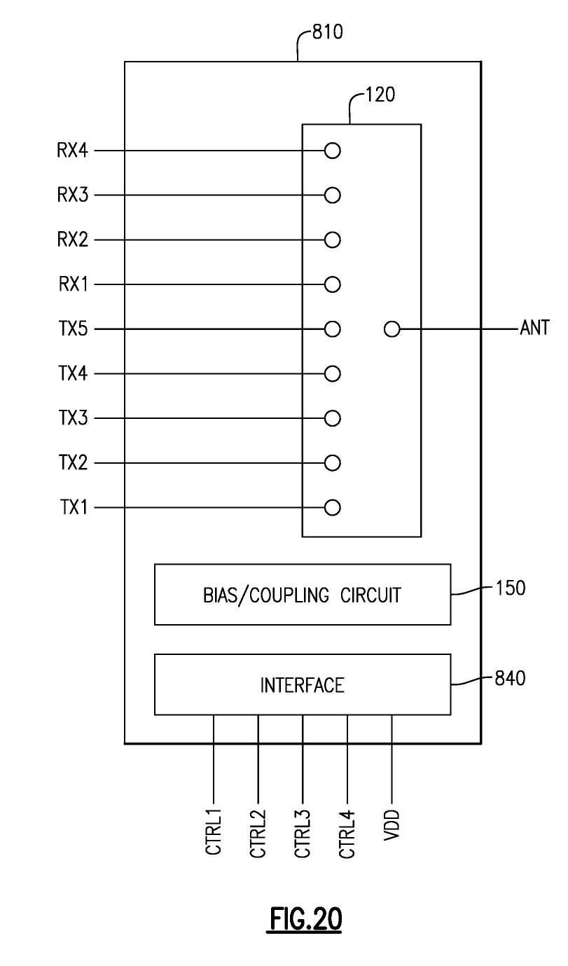

FIGS. 18A-18D schematically show non-limiting examples of such implementations on one or more semiconductor die. FIG. 18A shows that in some embodiments, a switch circuit 120 and a bias/coupling circuit 150 having one or more features as described herein can be implemented on a die 800. FIG. 18B shows that in some embodiments, at least some of the bias/coupling circuit 150 can be implemented outside of the die 800 of FIG. 18A.

FIG. 18C shows that in some embodiments, a switch circuit 120 having one or more features as described herein can be implemented on a first die 800a, and a bias/coupling circuit 150 having one or more features as described herein can be implemented on a second die 800b. FIG. 18D shows that in some embodiments, at least some of the bias/coupling circuit 150 can be implemented outside of the first die 800a of FIG. 18C.

### Packaged Module Implementation

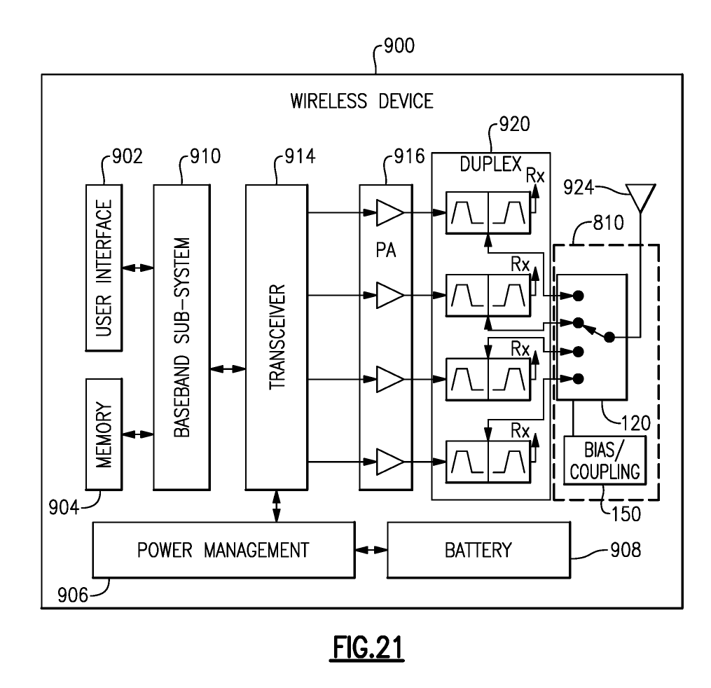

In some embodiments, one or more die having one or more features described herein can be implemented in a packaged module. An example of such a module is shown in FIGS. 19A (plan view) and 19B (side view). Although described in the context of both of the switch circuit and the bias/coupling circuit being on the same die (e.g., example configuration of FIG. 18A), it will be understood that packaged modules can be based on other configurations.

A module 810 is shown to include a packaging substrate 812. Such a packaging substrate can be configured to receive a plurality of components, and can include, for example, a laminate substrate. The components mounted on the packaging substrate 812 can include one or more dies. In the example shown, a die 800 having a switching circuit 120 and a bias/coupling circuit 150 is shown to be mounted on the packaging substrate 812. The die 800 can be electrically connected to other parts of the module (and with each other where more than one die is utilized) through connections such as connection-wirebonds 816. Such connection-wirebonds can be formed between contact pads 818 formed on the die 800 and contact pads 814 formed on the packaging substrate 812. In some embodiments, one or more surface mounted devices (SMDs) 822 can be mounted on the packaging substrate 812 to facilitate various functionalities of the module 810.

In some embodiments, the packaging substrate 812 can include electrical connection paths for interconnecting the various components with each other and/or with contact pads for external connections. For example, a connection path 832 is depicted as interconnecting the example SMD 822 and the die 800. In another example, a connection path 832 is depicted as interconnecting the SMD 822 with an external-connection contact pad 834. In yet another example a connection path 832 is depicted as interconnecting the die 800 with ground-connection contact pads 836.

In some embodiments, a space above the packaging substrate 812 and the various components mounted thereon can be filled with an overmold structure 830. Such an overmold structure can provide a number of desirable functionalities, including protection for the components and wirebonds from external elements, and easier handling of the packaged module 810.

FIG. 20 shows a schematic diagram of an example switching configuration that can be implemented in the module 810 described in reference to FIGS. 19A and 19B. In the example, the switch circuit 120 is depicted as being an SP9T switch, with the pole being connectable to an antenna and the throws being connectable to various Rx and Tx paths. Such a configuration can facilitate, for example, multi-mode multi-band operations in wireless devices.

The module 810 can further include an interface for receiving power (e.g., supply voltage VDD) and control signals to facilitate operation of the switch circuit 120 and/or the bias/coupling circuit 150. In some implementations, supply voltage and control signals can be applied to the switch circuit 120 via the bias/coupling circuit 150.

### Wireless Device Implementation

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

FIG. 21 schematically depicts an example wireless device 900 having one or more advantageous features described herein. In the context of various switches and various biasing/coupling configurations as described herein, a switch 120 and a bias/coupling circuit 150 can be part of a module 810. In some embodiments, such a switch module can facilitate, for example, multi-band multip-mode operation of the wireless device 900.

In the example wireless device 900, a power amplifier (PA) module 916 having a plurality of PAs can provide an amplified RF signal to the switch 120 (via a duplexer 920), and the switch 120 can route the amplified RF signal to an antenna. The PA module 916 can receive an unamplified RF signal from a transceiver 914 that can be configured and operated in known manners. The transceiver can also be configured to process received signals. The transceiver 914 is shown to interact with a baseband sub-system 910 that is configured to provide conversion between data and/or voice signals suitable for a user and RF signals suitable for the transceiver 914. The transceiver 914 is also shown to be connected to a power management component 906 that is configured to manage power for the operation of the wireless device 900. Such a power management component can also control operations of the baseband sub-system 910 and the module 810.

The baseband sub-system 910 is shown to be connected to a user interface 902 to facilitate various input and output of voice and/or data provided to and received from the user. The baseband sub-system 910 can also be connected to a memory 904 that is configured to store data and/or instructions to facilitate the operation of the wireless device, and/or to provide storage of information for the user.

In some embodiments, the duplexer 920 can allow transmit and receive operations to be performed simultaneously using a common antenna (e.g., 924). In FIG. 21, received signals are shown to be routed to “Rx” paths (not shown) that can include, for example, a low-noise amplifier (LNA).

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

Combination of Features from Different Examples:

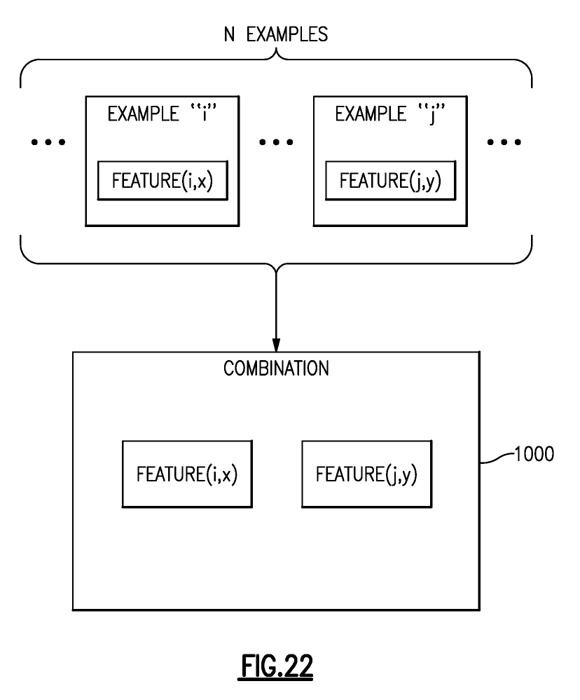

In some implementations, various features from different Examples described herein can be combined to yield one or more desirable configurations. FIG. 22 schematically depicts a combination configuration 1000 where a first feature (i,x) is shown to be combined with second feature (j,y). The indices “i” and “j” are for Example numbers among N Examples, with i=1, 2, . . . , N−1, N, and j=1, 2, . . . , N−1, N. In some implementations, i≠j for the first and second features of the combination configuration 1000. The index “x” can represent an individual feature associated with the i-th Example. The index “x” can also represent a combination of features associated with the i-th Example. Similarly, the index “y” can represent an individual feature associated with the j-th Example. The index “y” can also represent a combination of features associated with the j-th Example. As described herein, the value of N can be 12.

Although described in the context of combining features from two different Examples, it will be understood that features from more than two Examples can also be combined. For example, features from three, four, five, etc. Examples can be combined to yield a combination configuration.

### General Comments:

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A radio-frequency (RF) switch comprising:
a first field-effect transistor (FET) disposed between an input node and an output node; and
a switchable capacitor disposed between the input node and the output node, the switchable capacitor coupled in parallel with the first FET.

2. The RF switch of claim 1 wherein the first FET comprises a gate, a body, a drain and a source.

3. The RF switch of claim 2 wherein the input node is coupled to the source and the output node is coupled to the drain.

4. The RF switch of claim 3 wherein the switchable capacitor is coupled to the drain and the source.

5. The RF switch of claim 1 wherein the switchable capacitor is ON when the first FET is ON.

6. The RF switch of claim 1 wherein the switchable capacitor is OFF when the first FET is OFF.

7. The RF switch of claim 2 further comprising a resistor coupled to the gate.

8. The RF switch of claim 1 wherein the output node is configured to output a RF signal when the first FET is in an ON state.

9. The RF switch of claim 1 further comprising additional FETs connected in series to the first FET, a number of additional FETs selected to allow the RF switch to handle a power of a RF signal.

10. The RF switch of claim 1 wherein the first FET is a silicon-on-insulator (SOI) FET.

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. (canceled)

23. (canceled)

24. (canceled)

25. A radio-frequency (RF) switch module comprising:
a packaging substrate configured to receive a plurality of components;
a semiconductor die mounted on the packaging substrate, the semiconductor die including a first field-effect transistor (FET) disposed between an input node and an output node and a switchable capacitor disposed between the input node and the output node, the switchable capacitor coupled in parallel with the first FET.

26. The RF switch module of claim 25 wherein the semiconductor die is a silicon-on-insulator (SOI) die.

27. The RF switch module of claim 25 wherein the first FET comprises a gate, a body, a drain and a source.

28. The RF switch module of claim 27 wherein the input node is coupled to the source and the output node is coupled to the drain.

29. The RF switch module of claim 28 wherein the switchable capacitor is coupled to the drain and the source.

30. The RF switch module of claim 25 wherein the switchable capacitor is ON when the first FET is ON.

31. The RF switch module of claim 25 wherein the switchable capacitor is OFF when the first FET is OFF.

32. The RF switch module of claim 27 further comprising a resistor coupled to the gate.

33. (canceled)

34. The RF switch module of claim 25 further comprising additional FETs connected in series to the first FET, a number of additional FETs selected to allow the RF switch to handle a power of a RF signal.

35. (canceled)

36. A wireless device comprising:
a transceiver configured to process RF signals;
an antenna in communication with the transceiver configured to facilitate transmission of an amplified RF signal;
a power amplifier connected to the transceiver and configured to generate the amplified RF signal; and
a switch connected to the antenna and the power amplifier and configured to selectively route the amplified RF signal to the antenna, the switch including a a first field-effect transistor (FET) disposed between an input node and an output node and a switchable capacitor disposed between the input node and the output node, the switchable capacitor coupled in parallel with the first FET.

37.-46. (canceled)
